(19) United States
(12) Patent Application Publication
(10) Pub. No.: US 2026/0082613 A1
(43) Pub. Date: Mar. 19, 2026

(54) SEMICONDUCTOR DEVICE WITH DIPOLE PORTION AND METHOD FOR PREPARING THE SAME

(71) Applicant: NANYA TECHNOLOGY CORPORATION, NEW TAIPEI CITY (TW)

(72) Inventor: YU-HUA LIU, NEW TAIPEI CITY (TW)

(21) Appl. No.: 18/888,460

(22) Filed: Sep. 18, 2024

(51) Int. Cl. H01L 29/78; H01L 29/06; H01L 29/08

(52) U.S. Cl. CPC H10D 30/601; H10D 62/10; H10D 62/151

(57) ABSTRACT

A semiconductor device includes a gate structure disposed over a semiconductor substrate, and a dielectric layer surrounding the gate structure. The semiconductor device also includes a source region and a drain region disposed in the semiconductor substrate and on opposite sides of the gate structure. The semiconductor device further includes a first dipole portion disposed over the semiconductor substrate and covering the source region, and a first dielectric spacer disposed over the first dipole portion and adjacent to the dielectric layer.

### TECHNICAL FIELD

The present disclosure relates to a semiconductor device and a method for preparing the same, and more particularly, to a semiconductor device with a dipole portion and a method for preparing the same.

### DISCUSSION OF THE BACKGROUND

Semiconductor devices are essential for many modern applications. With the advancement of electronic technology, semiconductor devices are becoming smaller in size while providing greater functionality and including greater amounts of integrated circuitry. Due to the miniaturized scale of semiconductor devices, various types and dimensions of semiconductor devices providing different functionalities are integrated and packaged into a single module. Furthermore, numerous manufacturing operations are implemented for integration of various types of semiconductor devices.

However, the manufacturing and integration of semiconductor devices involve many complicated steps and operations. An increase in the complexity of manufacturing and miniaturization of semiconductor devices may cause deficiencies. For example, transistors with reduced channel lengths suffer from short-channel effects, such as increased off-state leakage current. Accordingly, there is a continuous need to improve the manufacturing process of semiconductor devices so that the problems can be addressed.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a semiconductor device is provided. The semiconductor device includes a gate structure disposed over a semiconductor substrate, and a dielectric layer surrounding the gate structure. The semiconductor device also includes a source region and a drain region disposed in the semiconductor substrate and on opposite sides of the gate structure. The semiconductor device further includes a first dipole portion disposed over the semiconductor substrate and covering the source region, and a first dielectric spacer disposed over the first dipole portion and adjacent to the dielectric layer.

In an embodiment, a top surface of the gate structure is covered by the dielectric layer. In an embodiment, the dielectric layer and the first dielectric spacer include different materials. In an embodiment, the first dielectric spacer is separated from the source region by the first dipole portion. In an embodiment, the semiconductor device further includes a source contact penetrating through the first dipole portion to directly contact the source region. In an embodiment, the semiconductor device further includes a first lightly doped region disposed in the semiconductor substrate and extending from the source region to the gate structure. In an embodiment, the first lightly doped region is in direct contact with the first dipole portion.

In an embodiment, the first lightly doped region is separated from the first dielectric spacer by the first dipole portion. In an embodiment, the semiconductor device further includes a first halo implant region disposed in the semiconductor substrate and extending from the source region to the gate structure, wherein the first lightly doped region is disposed over the first halo implant region. In an embodiment, the semiconductor device further includes a second dipole portion disposed over the semiconductor substrate and covering the drain region, wherein a material of the first dipole portion is the same as a material of the second dipole portion. In an embodiment, the semiconductor device further includes a drain contact penetrating through the second dipole portion to directly contact the drain region.

In an embodiment, the semiconductor device further includes a second dielectric spacer disposed over the second dipole portion and adjacent to the dielectric layer, wherein the second dielectric spacer is separated from the drain region by the second dipole portion. In an embodiment, the semiconductor device further includes a second lightly doped region disposed in the semiconductor substrate and extending from the drain region to the gate structure, wherein the second lightly doped region is in direct contact with the second dipole portion. In an embodiment, the semiconductor device further includes a second halo implant region disposed in the semiconductor substrate and extending from the drain region to the gate structure, wherein the second lightly doped region is disposed over the second halo implant region.

In another embodiment of the present disclosure, a semiconductor device is provided. The semiconductor device includes a gate structure disposed over a semiconductor substrate, and a source region and a drain region disposed in the semiconductor substrate and on opposite sides of the gate structure. The semiconductor device also includes a first lightly doped region disposed in the semiconductor substrate and extending from the source region to the gate structure, and a first dipole portion disposed over the semiconductor substrate and covering the source region and the first lightly doped region. The semiconductor device further includes a first dielectric spacer covering the first dipole portion.

In an embodiment, the first dipole portion is in direct contact with the source region and the first dielectric spacer. In an embodiment, the first lightly doped region is in direct contact with the first dipole portion. In an embodiment, the semiconductor device further includes a source contact penetrating through the first dipole portion to directly contact the source region, wherein the source contact is separated from the first dielectric spacer. In an embodiment, the semiconductor device further includes a first halo implant region disposed below the first lightly doped region, wherein the first lightly doped region and the first halo implant region have different conductivity types.

In an embodiment, the semiconductor device further includes a second dielectric spacer covering and in direct contact with the drain region, wherein the first dielectric spacer is separated from the source region by the first dipole portion. In an embodiment, the first lightly doped region is separated from the first dielectric spacer by the first dipole portion. In an embodiment, the first dipole portion is L-shaped in a cross-sectional view. In an embodiment, the semiconductor device further includes a first dielectric layer covering the gate structure, wherein the first dielectric spacer is separated from the gate structure by the first dielectric layer. In an embodiment, the first dipole portion is in direct contact with the first dielectric layer.

In an embodiment, the semiconductor device further includes a second dielectric layer covering the first dipole portion, the first dielectric spacer and the first dielectric layer. In an embodiment, the semiconductor device further includes a second lightly doped region disposed in the semiconductor substrate and extending from the drain region to the gate structure. In addition, the semiconductor device includes a second dipole portion disposed over the semiconductor substrate and covering the drain region and the second lightly doped region, wherein the drain region is separated from the second dielectric layer by the second dipole portion. In an embodiment, a material of the first dipole portion is the same as a material of the second dipole portion. In an embodiment, the drain region is covered by and in direct contact with the second dielectric layer.

In yet another embodiment of the present disclosure, a method for forming a semiconductor device is provided. The method includes forming a gate structure over a semiconductor substrate, and forming a first dielectric layer covering the gate structure. The method also includes depositing a dipole layer over the semiconductor substrate and the first dielectric layer, and performing an etching process on the dipole layer to form a first dipole portion. The method further includes forming a first dielectric spacer over the first dipole portion, and forming a source region and a drain region in the semiconductor substrate and on opposite sides of the gate structure after the first dielectric spacer is formed. The source region is covered by the first dipole portion.

In an embodiment, a top surface and sidewalls of the gate structure are covered by the first dielectric layer before the dipole layer is deposited. In an embodiment, the method further includes performing the etching process on the dipole layer to form a second dipole portion, and forming a second dielectric spacer over the second dipole portion, wherein the drain region is formed after the second dielectric spacer is formed, and the drain region is covered by the second dipole portion. In an embodiment, the first dipole portion is separated from the second dipole portion, and the first dipole portion and the second dipole portion are L-shaped in a cross-sectional view. In an embodiment, the method further includes forming a second dielectric layer covering the first dipole portion, the first dielectric spacer and the first dielectric layer, and forming a source contact penetrating through the second dielectric layer and the first dipole portion to directly contact the source region. In an embodiment, the source region is separated from the second dielectric layer by the first dipole portion.

In an embodiment, the drain region is in direct contact with the second dielectric layer. In an embodiment, the first dipole portion is in direct contact with the first dielectric layer. In an embodiment, the method further includes forming a first lightly doped region and a second lightly doped region in the semiconductor substrate before the dipole layer is deposited, wherein the source region is formed penetrating through the first lightly doped region, and the drain region is formed penetrating through the second lightly doped region.

In an embodiment, the first lightly doped region and the second lightly doped region are covered by the dipole layer and the first dielectric layer before the etching process is performed. In an embodiment, the method further includes forming a first halo implant region below the first lightly doped region and forming a second halo implant region below the second lightly doped region before the dipole layer is deposited. In an embodiment, the first halo implant region and the first lightly doped region have different conductivity types, wherein the second halo implant region and the second lightly doped region have different conductivity types.

Embodiments of a semiconductor device with a dipole portion and method for preparing the same are provided in the disclosure. In some embodiments, the semiconductor device includes a gate structure disposed over a semiconductor substrate, a source region and a drain region disposed in the semiconductor substrate and on opposite sides of the gate structure, and a dipole portion disposed over the semiconductor substrate and covering the source region. Depending on the conductivity type of the semiconductor device, the dipole portion serves to increase the on-state current and/or suppress the off-state leakage current. In addition, parasitic capacitance in the portion of the channel between the gate structure and the dipole portion can be decreased to enhance the operation speed of the semiconductor device. As a result, the performance of the semiconductor device can be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view illustrating a semiconductor device, in accordance with some embodiments.

FIG. 2 is a cross-sectional view illustrating a semiconductor device, in accordance with some other embodiments.

FIG. 3 is a flow diagram illustrating a method for forming a semiconductor device, in accordance with some embodiments.

FIG. 4 is a flow diagram illustrating a method for forming a semiconductor device, in accordance with some other embodiments.

FIG. 5 is a cross-sectional view illustrating an intermediate stage of forming a gate structure over a semiconductor substrate during the formation of the semiconductor device, in accordance with some embodiments.

FIG. 6 is a cross-sectional view illustrating an intermediate stage of sequentially forming a first dielectric layer and a patterned mask over the gate structure during the formation of the semiconductor device, in accordance with some embodiments.

FIG. 7 is a cross-sectional view illustrating an intermediate stage of etching the first dielectric layer using the patterned mask as a mask during the formation of the semiconductor device, in accordance with some embodiments.

FIG. 8 is a cross-sectional view illustrating an intermediate stage of forming a first lightly doped region, a second lightly doped region, a first halo implant region and a second halo implant region in the semiconductor substrate during the formation of the semiconductor device, in accordance with some embodiments.

FIG. 9 is a cross-sectional view illustrating an intermediate stage of depositing a dipole layer over the semiconductor substrate and the first dielectric layer during the formation of the semiconductor device, in accordance with some embodiments.

FIG. 10 is a cross-sectional view illustrating an intermediate stage of forming a patterned mask over the dipole layer during the formation of the semiconductor device, in accordance with some embodiments.

FIG. 11 is a cross-sectional view illustrating an intermediate stage of etching the dipole layer to form a first dipole portion and a second dipole portion during the formation of the semiconductor device, in accordance with some embodiments.

FIG. 12 is a cross-sectional view illustrating an intermediate stage of removing the patterned mask during the formation of the semiconductor device, in accordance with some embodiments.

FIG. 13 is a cross-sectional view illustrating an intermediate stage of forming a spacer layer over the first dipole portion, the second dipole portion and the first dielectric layer during the formation of the semiconductor device, in accordance with some embodiments.

FIG. 14 is a cross-sectional view illustrating an intermediate stage of forming a first dielectric spacer, a second dielectric spacer, a source region and a drain region during the formation of the semiconductor device, in accordance with some embodiments.

FIG. 15 is a cross-sectional view illustrating an intermediate stage of forming a second dielectric layer covering the first dipole portion, the second dipole portion, the first dielectric spacer, the second dielectric spacer, and the first dielectric layer during the formation of the semiconductor device, in accordance with some embodiments.

FIG. 16 is a cross-sectional view illustrating an intermediate stage of forming an interlayer dielectric layer over the second dielectric layer during the formation of the semiconductor device, in accordance with some embodiments.

FIG. 17 is a cross-sectional view illustrating an intermediate stage of forming an opening exposing the source region and an opening exposing the drain region during the formation of the semiconductor device, in accordance with some embodiments.

FIG. 18 is a cross-sectional view illustrating an intermediate stage of forming a patterned mask over the dipole layer during the formation of the semiconductor device, in accordance with some embodiments.

FIG. 19 is a cross-sectional view illustrating an intermediate stage of etching the dipole layer to form a first dipole portion during the formation of the semiconductor device, in accordance with some embodiments.

FIG. 20 is a cross-sectional view illustrating an intermediate stage of forming a first dielectric spacer, a second dielectric spacer, a source region, and a drain region during the formation of the semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

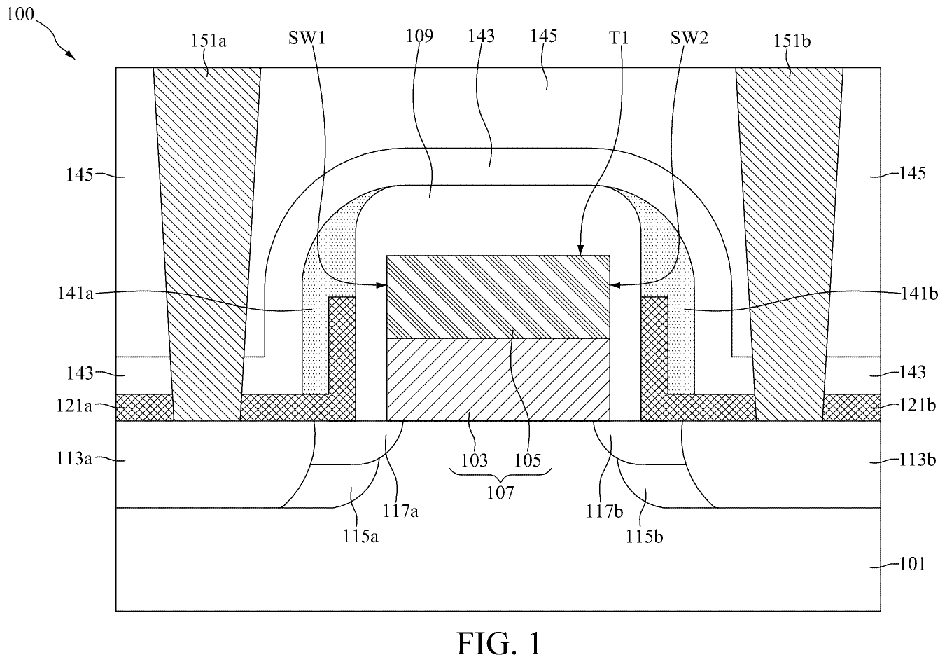

FIG. 1 is a cross-sectional view illustrating a semiconductor device 100, in accordance with some embodiments. In some embodiments, the semiconductor device 100 includes a semiconductor substrate 101 and a gate structure 107 disposed over the semiconductor substrate 101. In some embodiments, the gate structure 107 includes a gate dielectric layer 103 and a gate electrode layer 105 disposed over the gate dielectric layer 103.

In some embodiments, a source region 113a and a drain region 113b are disposed in the semiconductor substrate 101 and on opposite sides of the gate structure 107. In some embodiments, a lightly doped region 117a (also referred to as a first lightly doped region) and a halo implant region 115a (also referred to as a first halo implant region) are disposed in the semiconductor substrate 101 and extending from the source region 113a to the gate structure 107. In some embodiments, the lightly doped region 117a and the halo implant region 115a are disposed adjacent to the source region 113a, and the lightly doped region 117a is disposed over the halo implant region 115a.

In some embodiments, a lightly doped region 117b (also referred to as a second lightly doped region) and a halo implant region 115b (also referred to as a second halo implant region) are disposed in the semiconductor substrate 101 and extending from the drain region 113b to the gate structure 107. In some embodiments, the lightly doped region 117b and the halo implant region 115b are disposed adjacent to the drain region 113b, and the lightly doped region 117b is disposed over the halo implant region 115b.

In some embodiments, the source region 113a, the drain region 113b, and the lightly doped regions 117a and 117b have a first conductivity type, and the halo implant regions 115a and 115b have a second conductivity type opposite the first conductivity type. For example, the first conductivity type is n-type, and the second conductivity type is p-type. Moreover, in some embodiments, the dopant concentration of the source region 113a and the dopant concentration of drain region 113b are greater than the dopant concentrations of the lightly doped regions 117a and 117b.

In some embodiments, the semiconductor device 100 includes dipole portions 121a and 121b disposed over the semiconductor substrate 101. In some embodiments, the source region 113a is covered by the dipole portion 121a, and the drain region 113b is covered by the dipole portion 121b. The dipole portion 121a is also referred to as a first dipole portion, and the dipole portion 121b is also referred to as a second dipole portion.

In some embodiments, the lightly doped region 117a is partially covered by the dipole portion 121a, and the lightly doped region 117b is partially covered by the dipole portion 121b. In some embodiments, the dipole portion 121a is in direct contact with the source region 113a and the lightly doped region 117a, and the dipole portion 121b is in direct contact with the drain region 113b and the lightly doped region 117b. In some embodiments, a material of the dipole portion 121a is the same as a material of the dipole portion 121b.

In some embodiments, the semiconductor device 100 includes a dielectric layer 109 covering the gate structure 107, and dielectric spacers 141a and 141b disposed on opposite sides of the gate structure 107. In some embodiments, the top surface T1 and the sidewalls SW1, SW2 of the gate structure 107 are covered by the dielectric layer 109. In some embodiments, the dielectric spacers 141a and 141b are separated from the gate structure 107 by the dielectric layer 109. The dielectric spacer 141a is also referred to as a first dielectric spacer of the semiconductor device 100, and the dielectric spacer 141b is also referred to as a second dielectric spacer of the semiconductor device 100.

In some embodiments, the dielectric layer 109 is in direct contact with the dielectric spacer 141a and the dielectric spacer 141b. In some embodiments, the dielectric spacer 141a is in direct contact with the dipole portion 121a, and the dielectric spacer 141b is in direct contact with the dipole portion 121b. In some embodiments, the dipole portion 121a is L-shaped in the cross-sectional view of FIG. 1, and the dipole portion 121a extends between the dielectric spacer 141a and the dielectric layer 109. In some embodiments, the dipole portion 121b is L-shaped in the cross-sectional view of FIG. 1, and the dipole portion 121b extends between the dielectric spacer 141b and the dielectric layer 109.

In some embodiments, the lightly doped region 117a is partially covered by the dielectric spacer 141a, and the lightly doped region 117b is partially covered by the dielectric spacer 141b. In some embodiments, the dipole portion 121a is partially covered by the dielectric spacer 141a, and the dipole portion 121b is partially covered by the dielectric spacer 141b. In some embodiments, the material of the dielectric layer 109 is different from the material of the dielectric spacers 141a and 141b.

In some embodiments, the lightly doped region 117a is separated from the dielectric spacer 141a by the dipole portion 121a. In some embodiments, the lightly doped region 117b is separated from the dielectric spacer 141b by the dipole portion 121b. In some embodiments, the dielectric spacer 141a is separated from the source region 113a by the dipole portion 121a, and the dielectric spacer 141b is separated from the drain region 113b by the dipole portion 121b. In some embodiments, the dielectric layer 109 is in direct contact with the lightly doped region 117a and the lightly doped region 117b. In some embodiments, the lightly doped region 117a and the lightly doped region 117b extend to contact the gate dielectric layer 103 of the gate structure 107.

In some embodiments, the semiconductor device 100 includes a dielectric layer 143 covering the dipole portions 121a, 121b, the dielectric spacers 141a, 141b and the dielectric layer 109. The dielectric layer 109 is also referred to as a first dielectric layer, and the dielectric layer 143 is also referred to as a second dielectric layer. In some embodiments, the dielectric layer 143 is in direct contact with the dipole portions 121a and 121b, the dielectric spacers 141a and 141b, and the dielectric layer 109.

In some embodiments, the source region 113a is separated from the dielectric layer 143 by the dipole portion 121a, and the drain region 113b is separated from the dielectric layer 143 by the dipole portion 121b. In some embodiments, the dielectric spacer 141a is enclosed by the dipole portion 121a, the dielectric layer 109 and the dielectric layer 143. In some embodiments, the dielectric spacer 141b is enclosed by the dipole portion 121b, the dielectric layer 109 and the dielectric layer 143.

Still referring to FIG. 1, the semiconductor device 100 includes an interlayer dielectric (ILD) layer 145 disposed over the dielectric layer 143, a source contact 151a penetrating through the ILD layer 145, the dielectric layer 143 and the dipole portion 121a to contact the source region 113a, and a drain contact 151b penetrating through the ILD layer 145, the dielectric layer 143 and the dipole portion 121b to contact the drain region 113b, in accordance with some embodiments. In some embodiments, the source contact 151a is separated from the dielectric spacer 141a, and the drain contact 151b is separated from the dielectric spacer 141b.

In some embodiments, the semiconductor device 100 is an n-type field effect transistor (nFET), and the dipole portions 121a, 121b can be positive polarity dipole portions formed from a material inherently including a positive polarity. For example, the dipole portions 121a and 121b include yttrium (Y), lanthanum (La), strontium (Sr), yttrium oxide (Y₂O₃), lanthanum oxide (La₂O₃), strontium oxide (SrO), or a combination thereof. In such cases, the dipole portions 121a and 121b can help to increase on-state current of the nFET.

In some embodiments, the semiconductor device 100 is a p-type field effect transistor (pFET), and the dipole portions 121a, 121b can be negative polarity dipole portions formed from a material inherently including a negative polarity. For example, the dipole portions 121a and 121b include aluminum (Al), titanium (Ti), zirconium (Zr), hafnium (Hf), magnesium (Mg), aluminum oxide (Al₂O₃), titanium oxide (TiO₂), zirconium oxide (ZrO₂), hafnium oxide (HfO₂), magnesium oxide (MgO), or a combination thereof. In such cases, the dipole portions 121a and 121b can help to increase on-state current of the pFET.

In some embodiments, the semiconductor device 100 is an nFET, and the dipole portions 121a, 121b can be negative polarity dipole portions formed from a material inherently including a negative polarity. For example, the dipole portions 121a and 121b include aluminum (Al), titanium (Ti), zirconium (Zr), hafnium (Hf), magnesium (Mg), aluminum oxide (Al₂O₃), titanium oxide (TiO₂), zirconium oxide (ZrO₂), hafnium oxide (HfO₂), magnesium oxide (MgO), or a combination thereof. In such cases, the dipole portions 121a and 121b can help to suppress the off-state leakage current of the nFET. Moreover, parasitic capacitance in the portions of the channel between the gate structure 107 and the dipole portions 121a, 121b can be decreased to enhance the operation speed of the nFET.

In some embodiments, the semiconductor device 100 is a pFET, and the dipole portions 121a, 121b can be positive polarity dipole portions formed from a material inherently including a positive polarity. For example, the dipole portions 121a and 121b include yttrium (Y), lanthanum (La), strontium (Sr), yttrium oxide (Y₂O₃), lanthanum oxide (La₂O₃), strontium oxide (SrO), or a combination thereof. In such cases, the dipole portions 121a and 121b can help to suppress the off-state leakage current of the pFET. Moreover, parasitic capacitance in the portions of the channel between the gate structure 107 and the dipole portions 121a, 121b can be decreased to enhance the operation speed of the pFET.

Embodiments of the semiconductor device 100 with the dipole portions 121a and 121b and method for preparing the same are provided in the disclosure. In the present embodiment, the dipole portions 121a and 121b serve to increase the on-state current or suppress the off-state leakage current of the semiconductor device 100. In addition, parasitic capacitance in the portions of the channel between the gate structure 107 and the dipole portions 121a, 121b can be decreased to enhance the operation speed of the semiconductor device 100. As a result, the performance of the semiconductor device 100 can be improved.

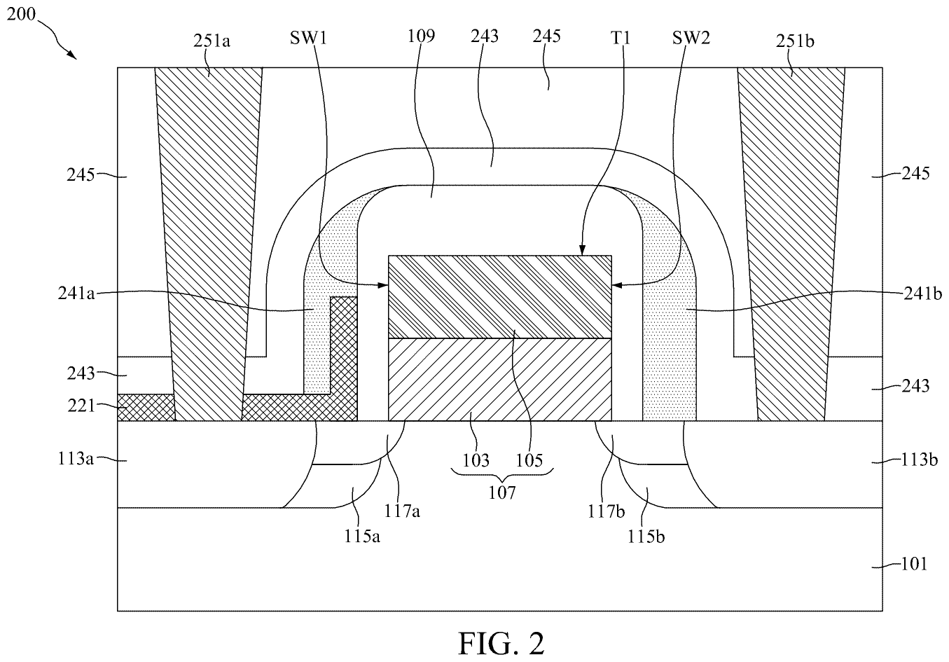

FIG. 2 is a cross-sectional view illustrating a semiconductor device 200, in accordance with some other embodiments. In some embodiments, the semiconductor device 200 includes a semiconductor substrate 101, a gate structure 107 disposed over the semiconductor substrate 101, and a dielectric layer 109 covering the top surface T1 and the sidewalls SW1, SW2 of the gate structure 107. In some embodiments, the gate structure 107 includes a gate dielectric layer 103 and a gate electrode layer 105. The features of the semiconductor substrate 101, the gate structure 107 and the dielectric layer 109 in the semiconductor device 200 are the same as, or similar to the semiconductor substrate 101, the gate structure 107 and the dielectric layer 109 in the semiconductor device 100, and therefore are not repeated.

In some embodiments, a source region 113a, a drain region 113b, lightly doped regions 117a and 117b, and halo implant regions 115a and 115b are disposed in the semiconductor substrate 101 of the semiconductor device 200. The features of the source region 113a, the drain region 113b, the lightly doped regions 117a, 117b and the halo implant regions 115a, 115b in the semiconductor device 200 are the same as, or similar to the source region 113a, the drain region 113b, the lightly doped regions 117a, 117b and the halo implant regions 115a, 115b in the semiconductor device 100, and therefore are not repeated.

In some embodiments, the semiconductor device 200 includes a dipole portion 221 (also referred to as a first dipole portion in the semiconductor device 200) disposed over the semiconductor substrate 101 and covering the source region 113a. In some embodiments, the lightly doped region 117a is partially covered by the dipole portion 221. In some embodiments, the dipole portion 221 is in direct contact with the source region 113a and the lightly doped region 117a.

In some embodiments, the semiconductor device 200 includes dielectric spacers 241a and 241b disposed on opposite sides of the gate structure 107, and a dielectric layer 243 covering the dipole portion 221, the dielectric spacers 241a, 241b and the dielectric layer 109. In some embodiments, the dielectric spacers 241a and 241b are separated from the gate structure 107 by the dielectric layer 109. In some embodiments, the dielectric layer 109 is in direct contact with the dielectric spacer 241a and the dielectric spacer 241b. The dielectric spacer 241a is also referred to as a first dielectric spacer of the semiconductor device 200, and the dielectric spacer 241b is also referred to as a second dielectric spacer of the semiconductor device 200.

In some embodiments, the dielectric spacer 241a is in direct contact with the dipole portion 221. In some embodiments, the dipole portion 221 is L-shaped in the cross-sectional view of FIG. 2, and the dipole portion 221 extends between the dielectric spacer 241a and the dielectric layer 109. In some embodiments, the lightly doped region 117a is partially covered by the dielectric spacer 241a, and the lightly doped region 117b is partially covered by the dielectric spacer 241b. In some embodiments, the dipole portion 221 is partially covered by the dielectric spacer 241a.

In some embodiments, the material of the dielectric layer 109 is different from the material of the dielectric spacers 241a and 241b. In some embodiments, the lightly doped region 117a is separated from the dielectric spacer 241a by the dipole portion 221. In some embodiments, the lightly doped region 117b is in direct contact with the dielectric spacer 241b. In some embodiments, the dielectric layer 109 is in direct contact with the lightly doped region 117a and the lightly doped region 117b. In some embodiments, the lightly doped region 117a and the lightly doped region 117b extend to contact the gate dielectric layer 103 of the gate structure 107.

In some embodiments, the dielectric spacer 241a is separated from the source region 113a by the dipole portion 221, and the dielectric spacer 241b is in direct contact with the drain region 113b. In addition, the dielectric layer 109 is also referred to as a first dielectric layer, and the dielectric layer 243 is also referred to as a second dielectric layer. In some embodiments, the source region 113a is separated from the dielectric layer 243 by the dipole portion 221, and the drain region 113b is covered by and in direct contact with the dielectric layer 243. In some embodiments, the dielectric layer 243 is in direct contact with the dipole portion 221, the dielectric spacers 241a and 241b, and the dielectric layer 109. In some embodiments, the dielectric spacer 241a is enclosed by the dipole portion 221, the dielectric layer 109 and the dielectric layer 243.

Still referring to FIG. 2, the semiconductor device 200 includes an ILD layer 245 disposed over the dielectric layer 243, a source contact 251a penetrating through the ILD layer 245, the dielectric layer 243 and the dipole portion 221 to contact the source region 113a, and a drain contact 251b penetrating through the ILD layer 245 and the dielectric layer 243 to contact the drain region 113b, in accordance with some embodiments. In some embodiments, the source contact 251a is separated from the dielectric spacer 241a, and the drain contact 251b is separated from the dielectric spacer 241b.

In some embodiments, the semiconductor device 100 is an nFET, and the dipole portion 221 can be a positive polarity dipole portion formed from a material inherently including a positive polarity. For example, the dipole portion 221 includes yttrium (Y), lanthanum (La), strontium (Sr), yttrium oxide (Y₂O₃), lanthanum oxide (La₂O₃), strontium oxide (SrO), or a combination thereof. In such cases, the dipole portion 221 can help to increase on-state current of the nFET while avoiding increase in off-state leakage current.

In some embodiments, the semiconductor device 200 is a pFET, and the dipole portion 221 can be a negative polarity dipole portion formed from a material inherently including a negative polarity. For example, the dipole portion 221 includes aluminum (Al), titanium (Ti), zirconium (Zr), hafnium (Hf), magnesium (Mg), aluminum oxide (Al₂O₃), titanium oxide (TiO₂), zirconium oxide (ZrO₂), hafnium oxide (HfO₂), magnesium oxide (MgO), or a combination thereof. In such cases, the dipole portion 221 can help to increase on-state current of the pFET while avoiding increase in off-state leakage current.

Embodiments of the semiconductor device 200 with the dipole portion 221 and method for preparing the same are provided in the disclosure. In the present embodiment, the dipole portion 221 serves to increase the on-state current and suppress the off-state leakage current of the semiconductor device 200. As a result, the performance of the semiconductor device 200 can be improved.

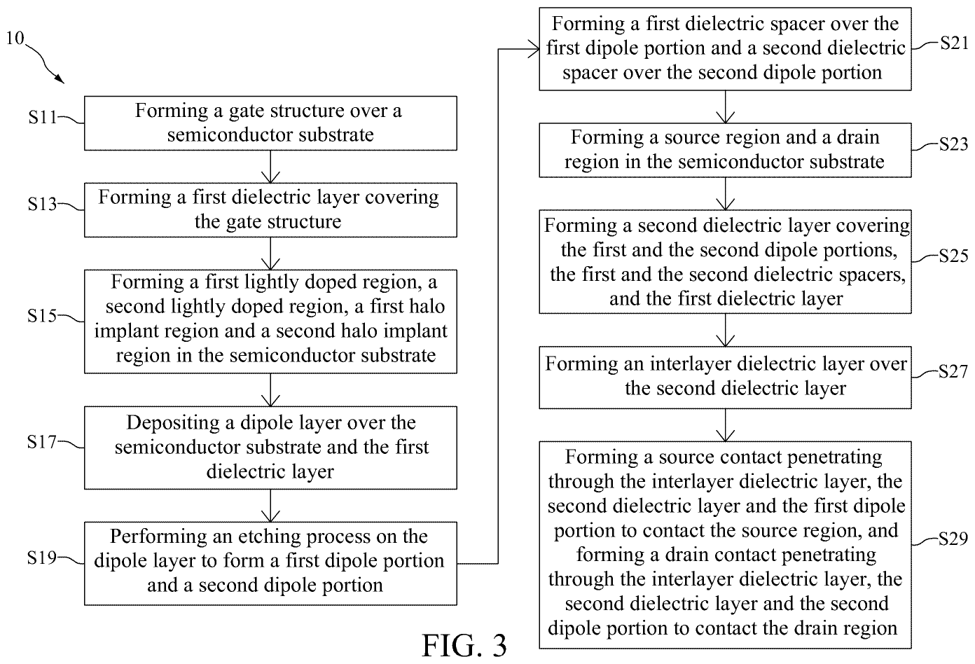

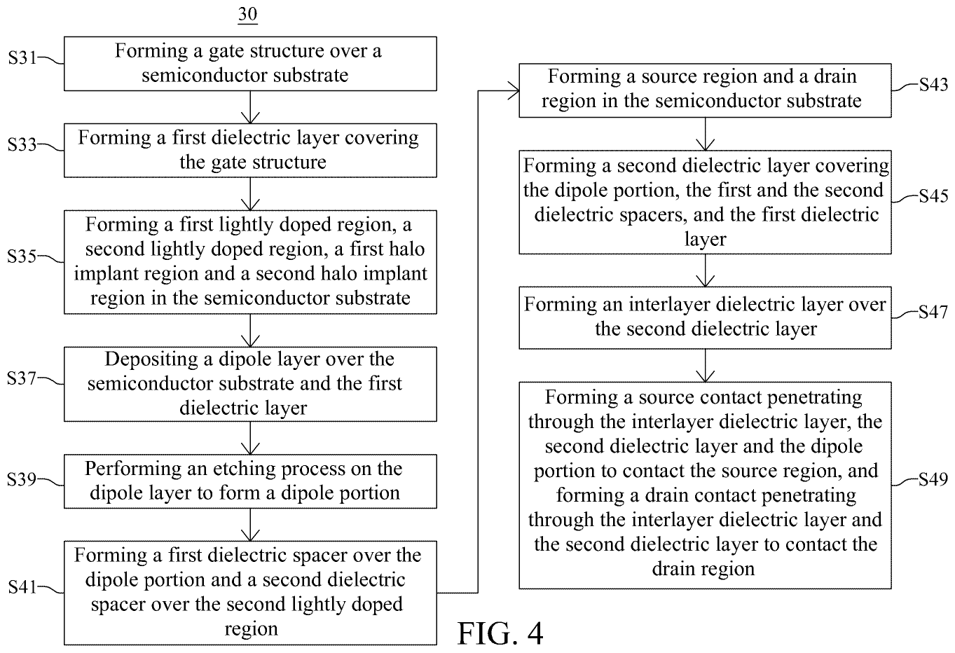

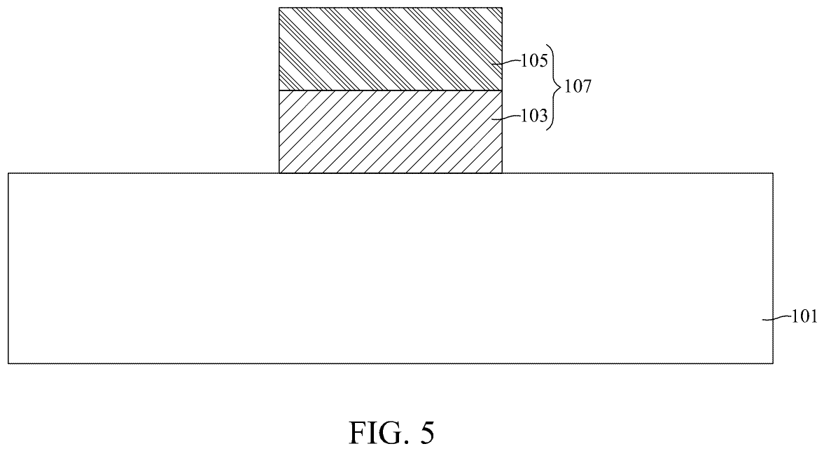

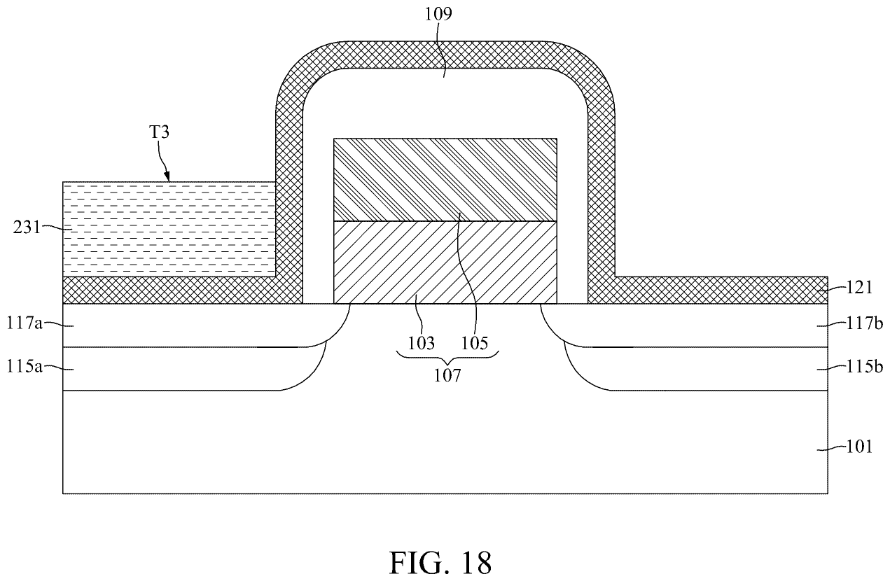

FIG. 3 is a flow diagram illustrating a method 10 for forming the semiconductor device 100, and the method 10 includes steps S11, S13, S15, S17, S19, S21, S23, S25, S27, and S29, FIG. 4 is a flow diagram illustrating a method 30 for forming the semiconductor device 200, and the method 30 includes steps S31, S33, S35, S37, S39, S41, S43, S45, S47, and S49, in accordance with some embodiments. The steps S11 to S29 of FIG. 3 are elaborated in connection with FIGS. 5 to 17. The steps S31 to S49 of FIG. 4 are elaborated in connection with FIGS. 18 to 20.

FIGS. 5 to 17 are cross-sectional views illustrating intermediate stages during the formation of the semiconductor device 100, in accordance with some embodiments. As shown in FIG. 5, a semiconductor substrate 101 is provided, in accordance with some embodiments.

The semiconductor substrate 101 may be a semiconductor wafer such as a silicon wafer. Alternatively or additionally, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

Still referring to FIG. 5, a gate structure 107 including a gate dielectric layer 103 and a gate electrode layer 105 is formed over the semiconductor substrate 101, in accordance with some embodiments. The respective step is illustrated as the step S11 in the method 10 shown in FIG. 3. In some embodiments, the gate electrode layer 105 is formed over the gate dielectric layer 103.

In some embodiments, the gate dielectric layer 103 includes a dielectric material, such as silicon oxide, silicon nitride, silicon oxynitride, a high-k dielectric material, another suitable dielectric material, or a combination thereof. In some embodiments, the gate electrode layer 105 includes a conductive material, such as polysilicon, aluminum (Al), tungsten (W), copper (Cu), titanium (Ti), tantalum (Ta), a metal alloy, another suitable material, or a combination thereof.

In some embodiments, the formation of the gate structure 107 includes sequentially depositing a gate dielectric material (not shown) and a gate electrode material (not shown) over the semiconductor substrate 101, forming a patterned mask (not shown) over the gate electrode material, and performing an etching process on the gate electrode material and the gate dielectric material using the patterned mask as an etching mask. In some embodiments, the gate dielectric material and the gate electrode material are deposited by chemical vapor deposition (CVD), physical vapor deposition (PVD), atomic layer deposition (ALD), spin-on coating, or other suitable deposition processes.

In some embodiments, the etching process includes a wet etching process, a dry etching process, or a combination thereof. After gate structure 107 is formed, the patterned mask may be removed. In some embodiments, the patterned mask is removed by a stripping process, an ashing process, an etching process, or another suitable process.

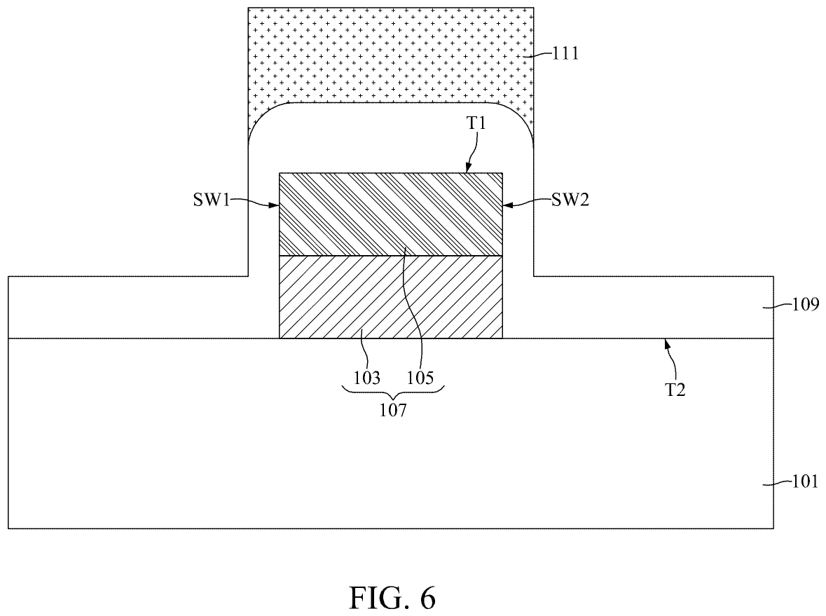

Next, a dielectric layer 109 is formed covering the semiconductor substrate 101 and the gate structure 107, and a patterned mask 111 is formed over the dielectric layer 109, as shown in FIG. 6 in accordance with some embodiments. In some embodiments, the top surface T1 and the opposite sidewalls SW1, SW2 of the gate structure 107 are covered by the dielectric layer 109. In some embodiments, the top surface T2 of the semiconductor substrate 101 is covered by the dielectric layer 109.

In some embodiments, the patterned mask 111 is disposed over the gate structure 107 and separated from the gate structure 107 by the dielectric layer 109. In some embodiments, the dielectric layer 109 includes silicon oxide, silicon nitride, silicon oxynitride, another dielectric material, or a combination thereof. In some embodiments, the dielectric layer 109 is formed by a deposition process, such as a CVD process, a PVD process, an ALD process, a spin-on coating process, or another suitable deposition process.

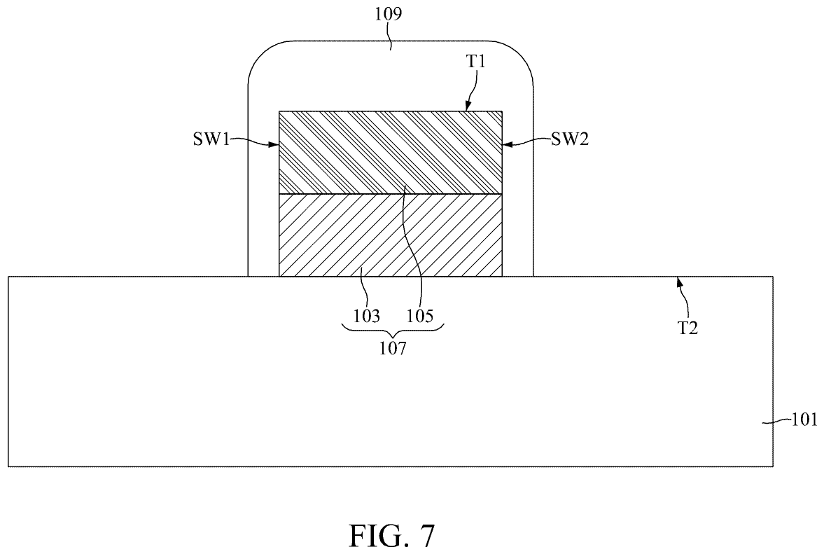

Subsequently, an etching process is performed on the dielectric layer 109 using the patterned mask 111 as an etching mask, as shown in FIG. 7 in accordance with some embodiments. In some embodiments, the top surface T2 of the semiconductor substrate 101 is exposed, while the top surface T1 and the opposite sidewalls SW1, SW2 of the gate structure 107 remain covered by the remaining portion of the dielectric layer 109 after the etching process is performed. The respective step is illustrated as the step S13 in the method 10 shown in FIG. 3.

In some embodiments, the etching process includes a wet etching process, a dry etching process, or a combination thereof. After the etching process is performed, the patterned mask 111 may be removed. In some embodiments, the patterned mask 111 is removed by a stripping process, an ashing process, an etching process, or another suitable process.

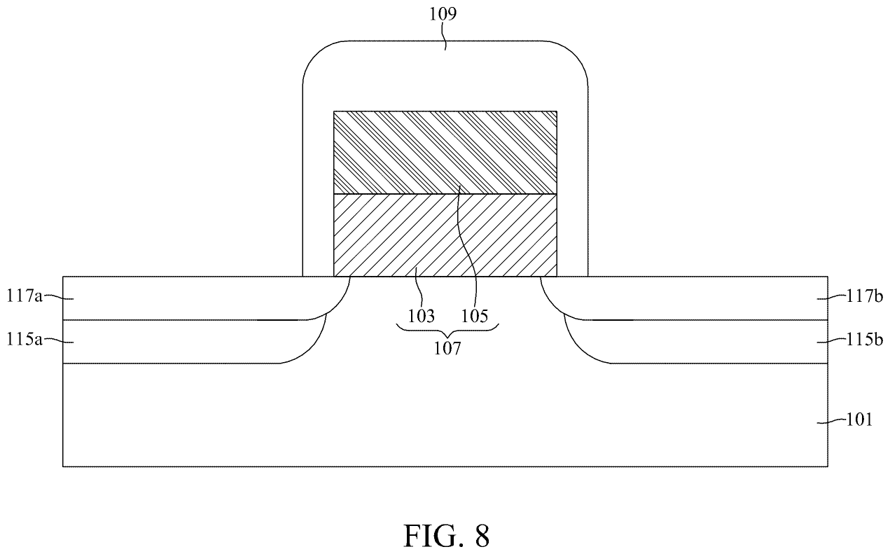

Then, lightly doped regions 117a and 117b, and halo implant regions 115a and 115b are formed in the semiconductor substrate 101, as shown in FIG. 8 in accordance with some embodiments. In some embodiments, the lightly doped region 117a and the halo implant region 115a are located on one side of the gate structure 107, while the lightly doped region 117b and the halo implant region 115b located on the other side of the gate structure 107. The respective step is illustrated as the step S15 in the method 10 shown in FIG. 3.

In some embodiments, the halo implant region 115a is disposed below the lightly doped region 117a. In some embodiments, the halo implant region 115b is disposed below the lightly doped region 117b. In some embodiments, the lightly doped regions 117a and 117b extend to directly contact the dielectric layer 109. In some embodiments, the lightly doped regions 117a and 117b further extend to directly contact the gate dielectric layer 103 of the gate structure 107. In some embodiments, the halo implant regions 115a and 115b extend directly below the dielectric layer 109.

In some embodiments, the lightly doped regions 117a and 117b, and the halo implant regions 115a and 115b are formed by ion implantation processes using the dielectric layer 109 as an ion implantation mask. In some embodiments, the ion implantation processes are tilted ion implantations applied to the semiconductor substrate 101 with tilt angles.

As mentioned above, the lightly doped regions 117a and 117b have a first conductivity type, and the halo implant regions 115a and 115b have a second conductivity type opposite the first conductivity type, in accordance with some embodiments. For example, the first conductivity type is n-type, and the second conductivity type is p-type.

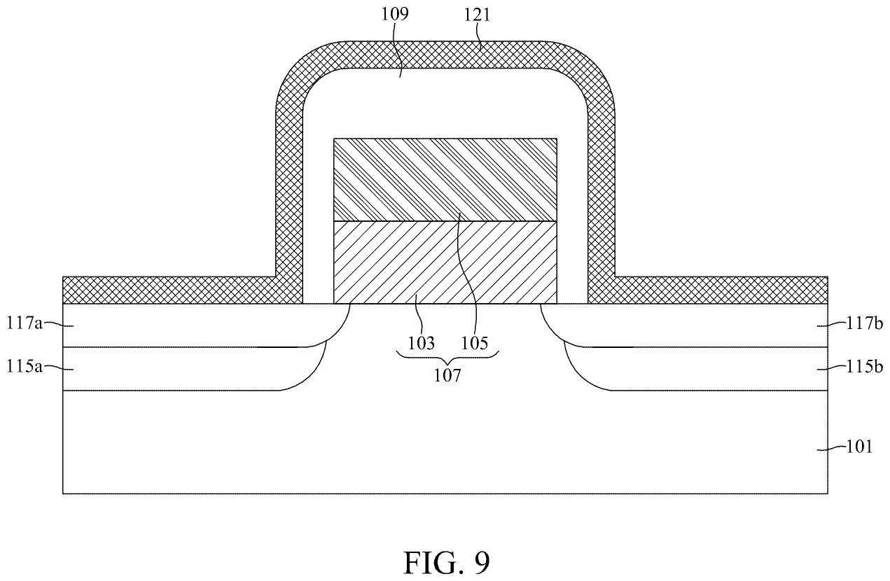

Next, a dipole layer 121 is deposited over the semiconductor substrate 101 and the dielectric layer 109, as shown in FIG. 9 in accordance with some embodiments. The respective step is illustrated as the step S17 in the method 10 shown in FIG. 3. In some embodiments, the lightly doped region 117a, the halo implant region 115a, the lightly doped region 117b, and the halo implant region 115b are covered by the dipole layer 121. In some embodiments, the lightly doped regions 117a and 117b are covered by and in direct contact with the dipole layer 121.

In some embodiments, the dipole layer 121 includes a material inherently including a positive or negative polarity depending on design requirements of the semiconductor device 100. In some embodiments, the dipole layer 121 includes aluminum (Al), titanium (Ti), zirconium (Zr), hafnium (Hf), magnesium (Mg), aluminum oxide (Al₂O₃), titanium oxide (TiO₂), zirconium oxide (ZrO₂), hafnium oxide (HfO₂), magnesium oxide (MgO), yttrium (Y), lanthanum (La), strontium (Sr), yttrium oxide (Y₂O₃), lanthanum oxide (La₂O₃), strontium oxide (SrO), or a combination thereof. In some embodiments, the dipole layer 121 is formed by a deposition process, such as a CVD process, a PVD process, an ALD process, a spin-on coating process, or another suitable deposition process.

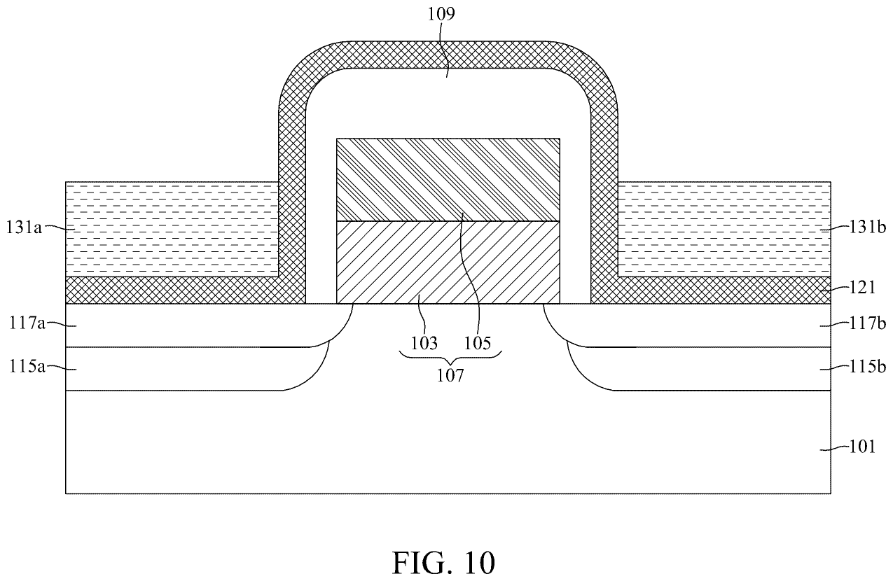

Subsequently, a patterned mask with patterns 131a and 131b is formed over the dipole layer 121, as shown in FIG. 10 in accordance with some embodiments. In some embodiments, the pattern 131a is disposed over the lightly doped region 117a and separated from the lightly doped region 117a by the dipole layer 121, and the pattern 131b is disposed over the lightly doped region 117b and separated from the lightly doped region 117b by the dipole layer 121.

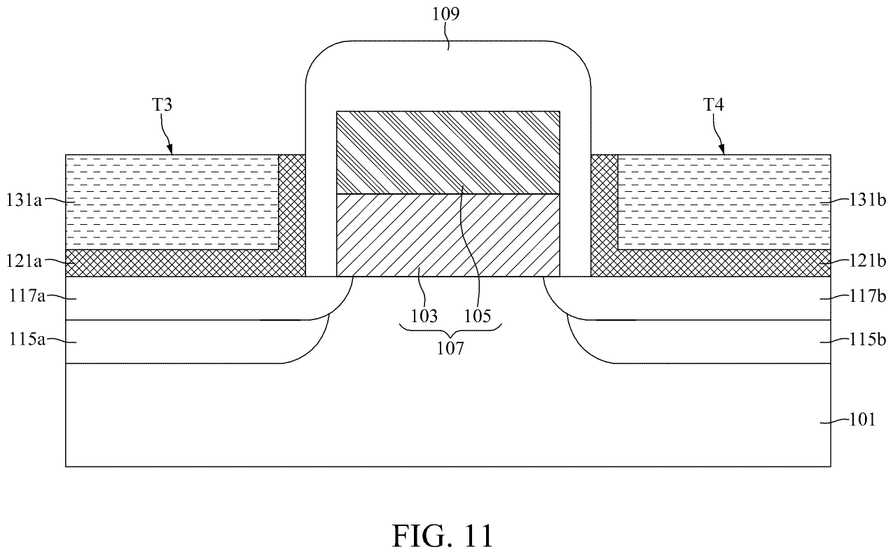

Then, an etching process is performed on the dipole layer 121 using the patterned mask with the patterns 131a and 131b as an etching mask, as shown in FIG. 11 in accordance with some embodiments. In some embodiments, the portion of the dipole layer 121 covering the dielectric layer 109 is removed by the etching process, such that a dipole portion 121a covering the lightly doped region 117a and a dipole portion 121b covering the lightly doped region 117b are formed. In some embodiments, the portion of the dipole layer 121 over the top surface T3 of the pattern 131a of the patterned mask and the portion of the dipole layer 121 over the top surface T4 of the pattern 131b of the patterned mask are removed by the etching process. The respective step is illustrated as the step S19 in the method 10 shown in FIG. 3.

In some embodiments, after the etching process is performed, the pattern 131a of the patterned mask is separated from the dielectric layer 109 by the dipole portion 121a, and the dipole portion 121a is L-shaped from the cross-sectional view of FIG. 11. In some embodiments, after the etching process is performed, the pattern 131b of the patterned mask is separated from the dielectric layer 109 by the dipole portion 121b, and the dipole portion 121b is L-shaped from the cross-sectional view of FIG. 11. In some embodiments, the dipole portions 121a and 121b are located on opposite sides of the gate structure 107. In some embodiments, the etching process includes a wet etching process, a dry etching process, or a combination thereof.

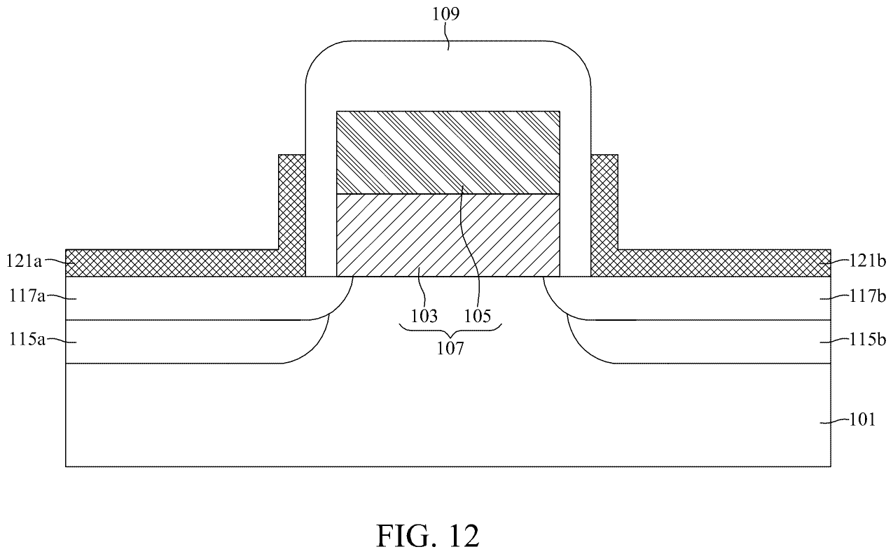

Next, the patterns 131a and 131b of the patterned mask are removed, as shown in FIG. 12 in accordance with some embodiments. In some embodiments, the patterns 131a and 131b are removed by a stripping process, an ashing process, an etching process, or another suitable process. After the patterns 131a and 131b are removed, the portion of the dipole portion 121a sandwiched between the pattern 131a and the lightly doped region 117a is exposed, and the portion of the dipole portion 121b sandwiched between the pattern 131b and the lightly doped region 117b is exposed, in accordance with some embodiments.

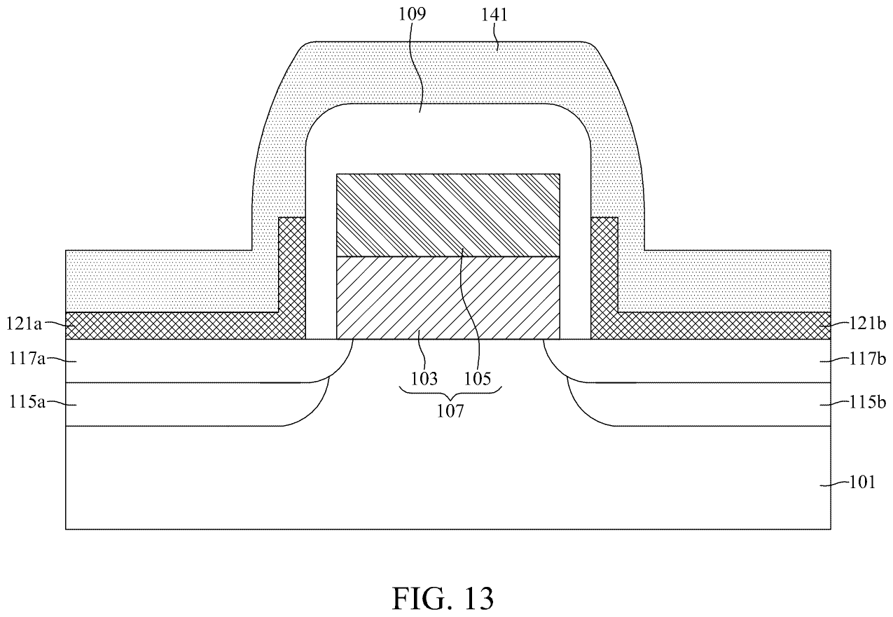

Subsequently, a spacer layer 141 is formed covering the dipole portions 121a, 121b and the dielectric layer 109, as shown in FIG. 13 in accordance with some embodiments. In some embodiments, the lightly doped region 117a is separated from the spacer layer 141 by the dipole portion 121a. In some embodiments, the lightly doped region 117b is separated from the spacer layer 141 by the dipole portion 121b. In some embodiments, the spacer layer 141 is in direct contact with the dipole portions 121a, the dielectric layer 109 and the dipole portion 121b.

In some embodiments, the spacer layer 141 includes a dielectric material, such as silicon oxide, silicon nitride, silicon oxynitride, another suitable dielectric material, or a combination thereof. In some embodiments, the spacer layer 141 and the dielectric layer 109 include different materials so that the etching selectivities may be different in the subsequent etching process. In some embodiments, the spacer layer 141 is formed by a deposition process, such as a CVD process, a PVD process, an ALD process, a spin-on coating process, or another suitable deposition process.

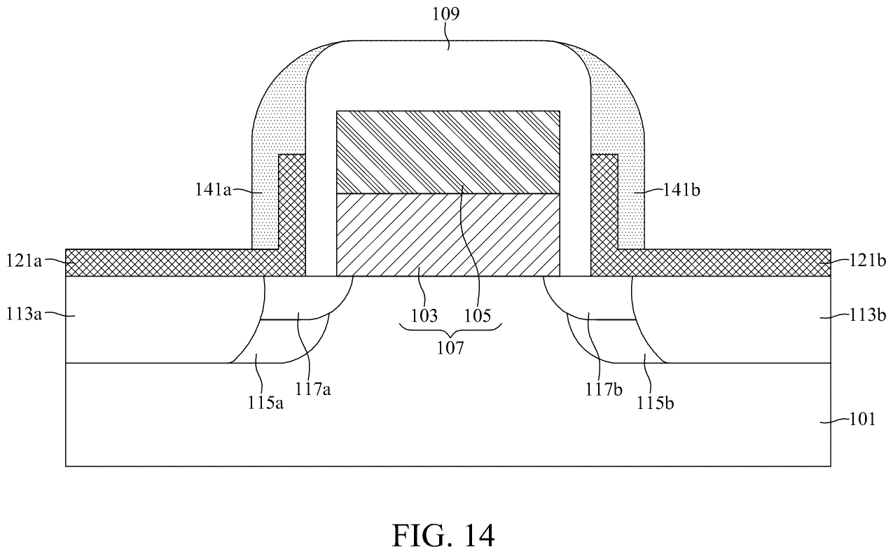

Then, an etching process is performed on the spacer layer 141 to form dielectric spacers 141a and 141b on opposite sides of the gate structure 107, as shown in FIG. 14 in accordance with some embodiments. In some embodiments, the dielectric spacer 141a is formed over the dipole portion 121a and in direct contact with the dielectric layer 109, and the dielectric spacer 141b is formed over the dipole portion 121b and in direct contact with the dielectric layer 109. In some embodiments, the dipole portion 121a is partially covered by the dielectric spacer 141a, and the dipole portion 121b is partially covered by the dielectric spacer 141b. The respective step is illustrated as the step S21 in the method 10 shown in FIG. 3. In some embodiments, the etching process is an anisotropic etching process.

Moreover, a source region 113a and a drain region 113b are formed in the semiconductor substrate 101, as shown in FIG. 14 in accordance with some embodiments. The respective step is illustrated as the step S23 in the method 10 shown in FIG. 3. In some embodiments, the source region 113a and the drain region 113b are located on opposite sides of the gate structure 107. In some embodiments, the source region 113a is formed penetrating through the lightly doped region 117a and the halo implant region 115a, and the drain region 113b is formed penetrating through the lightly doped region 117b and the halo implant region 115b.

In some embodiments, the lightly doped region 117a and the halo implant region 115a are located between the source region 113a and the gate structure 107, and the lightly doped region 117b and the halo implant region 115b are located between the drain region 113b and the gate structure 107. In some embodiments, the source region 113a and the drain region 113b are formed by ion implantation process using the dielectric spacers 141a, 141b and the dielectric layer 109 as an ion implantation mask. In some embodiments, the ion implantation process is tilted ion implantation applied to the semiconductor substrate 101 with a tilt angle.

As mentioned above, the source region 113a, the drain region 113b, and the lightly doped regions 117a and 117b have a first conductivity type, and the halo implant regions 115a and 115b have a second conductivity type opposite the first conductivity type, in accordance with some embodiments. For example, the first conductivity type is n-type, and the second conductivity type is p-type. In addition, the dopant concentrations of the source region 113a and the drain region 113b are greater than the dopant concentrations of the lightly doped regions 117a and 117b, in accordance with some embodiments.

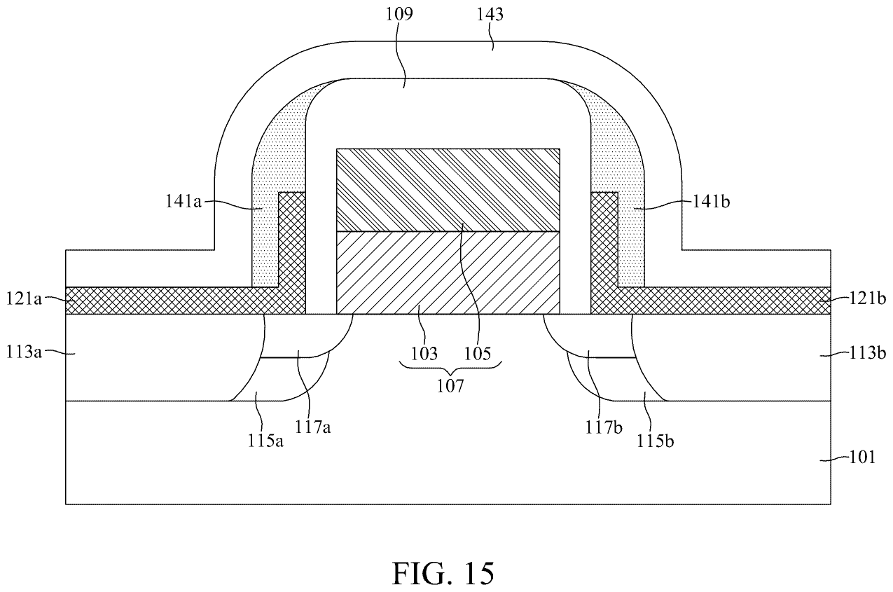

Next, a dielectric layer 143 is formed covering the dipole portions 121a and 121b, the dielectric spacers 141a and 141b, and the dielectric layer 109, as shown in FIG. 15 in accordance with some embodiments. The respective step is illustrated as the step S25 in the method 10 shown in FIG. 3. Some materials and processes used to form the dielectric layer 143 are similar to, or the same as those used to form the dielectric layer 109, and details thereof are not repeated herein.

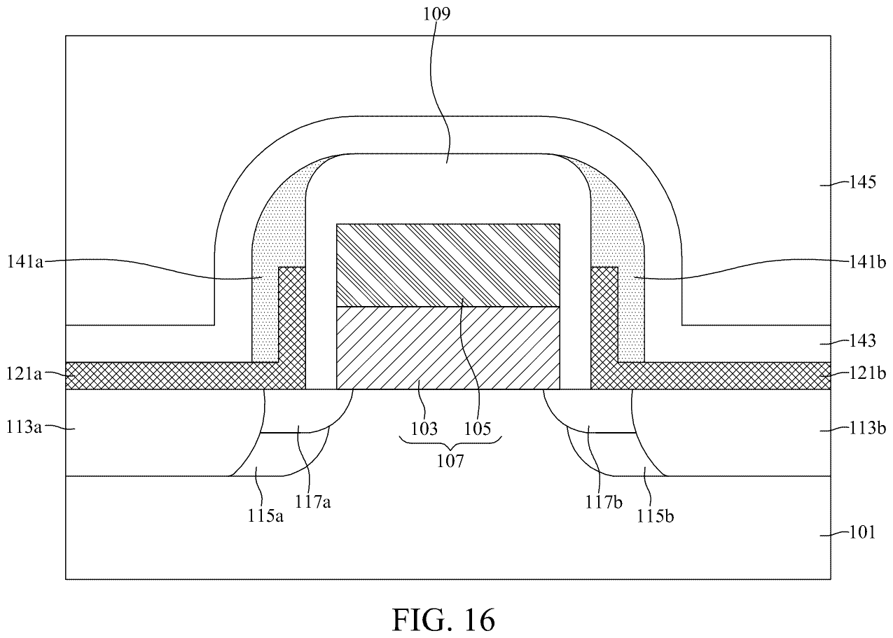

Subsequently, an ILD layer 145 is formed covering the dielectric layer 143, as shown in FIG. 16 in accordance with some embodiments. The respective step is illustrated as the step S27 in the method 10 shown in FIG. 3. In some embodiments, the ILD layer 145 includes a dielectric layer, such as silicon oxide, silicon nitride, silicon oxynitride, tetraethylorthosilicate (TEOS) formed oxide, undoped silicate glass, doped silicon oxide (e.g., phosphosilicate glass (PSG), borophosphosilicate glass (BPSG), boron doped silicon glass (BSG)), a low-k dielectric material, another suitable dielectric material, or a combination thereof. The ILD layer 145 may be formed by a deposition process, such as a CVD process, a PVD process, an ALD process, a spin-on coating process, or another suitable deposition process.

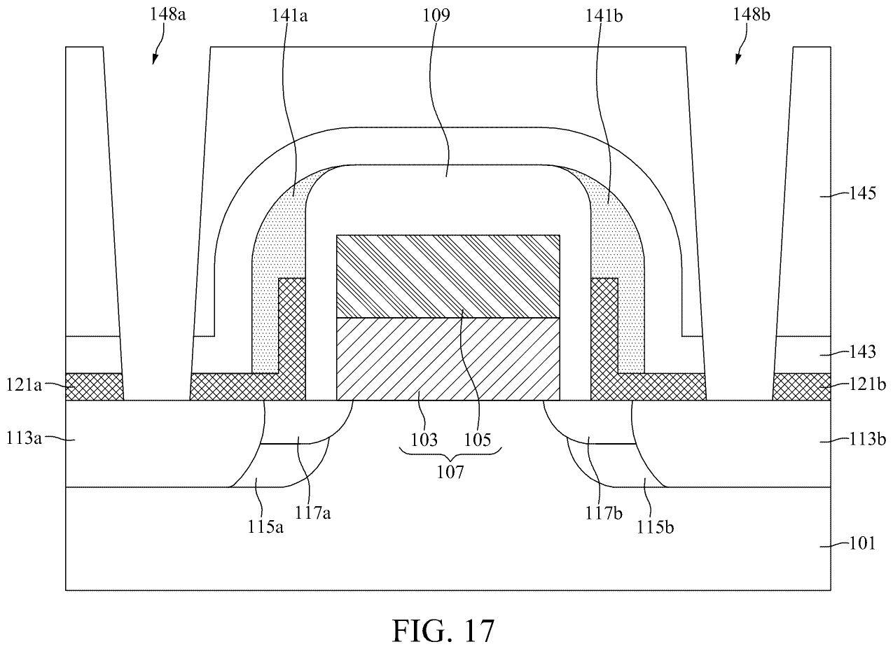

Then, an opening 148a is formed penetrating through the ILD layer 145, the dielectric layer 143 and the dipole portion 121a to expose the source region 113a, and an opening 148b is formed penetrating through the ILD layer 145, the dielectric layer 143 and the dipole portion 121b to expose the drain region 113b, as shown in FIG. 17 in accordance with some embodiments. In some embodiments, the formation of the openings 148a and 148b include forming a patterned mask (not shown) over the ILD layer 145, and performing an etching process using the patterned mask as an etching mask. In some embodiments, the etching process includes a wet etching process, a dry etching process, or a combination thereof. After the openings 148a and 148b are formed, the patterned mask may be removed.

Next, a source contact 151a and a drain contact 151b are formed in the openings 148a and 148b, respectively, as shown in FIG. 1 in accordance with some embodiments. In some embodiments, the source contact 151a is electrically connected to the source region 113a, and the drain contact 151b is electrically connected to the drain region 113b. In some embodiments, the source contact 151a is in direct contact with the source region 113a, and the drain contact 151b is in direct contact with the drain region 113b. The respective step is illustrated as the step S29 in the method 10 shown in FIG. 3.

In some embodiments, the source contact 151a and the drain contact 151b include aluminum (Al), copper (Cu), tungsten (W), titanium (Ti), tantalum (Ta), a combination thereof, or another suitable conductive material. In some embodiments, the source contact 151a and the drain contact 151b are formed by a deposition process and a planarization process. The deposition process may include a CVD process, a PVD process, an ALD process, a plating process, or another suitable deposition process. The planarization process may include a chemical mechanical polishing (CMP) process. After the source contact 151a and the drain contact 151b are formed, the semiconductor device 100 is obtained.

FIGS. 18 to 20 are cross-sectional views illustrating intermediate stages during the formation of the semiconductor device 200, in accordance with some embodiments. It should be pointed out that operations before the structure shown in FIG. 18 are substantially the same as the operations shown in FIGS. 5 to 9, and the related detailed descriptions may refer to the foregoing paragraphs and are not discussed again herein. The respective steps illustrated as the steps S31, S33, S35 and S37 in the method 30 shown in FIG. 4 are substantially the same as the steps S11, S13, S15 and S17 in the method 10 shown in FIG. 3.

After the dipole layer 121 is formed, a patterned mask 231 is formed over the dipole layer 121, as shown in FIG. 18 in accordance with some embodiments. In some embodiments, the patterned mask 231 is disposed over the lightly doped region 117a and separated from the lightly doped region 117a by the dipole layer 121.

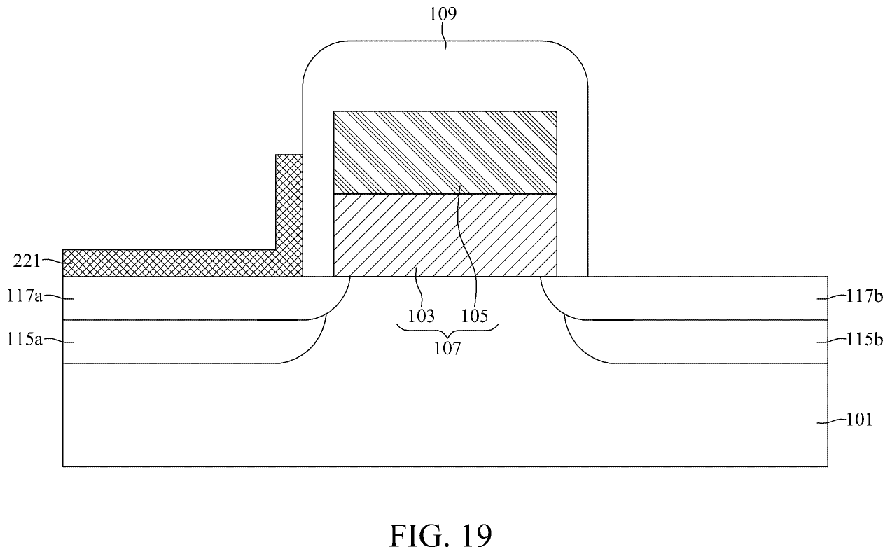

Next, an etching process is performed on the dipole layer 121 using the patterned mask 231 as an etching mask, as shown in FIG. 19 in accordance with some embodiments. In some embodiments, the portion of the dipole layer 121 covering the dielectric layer 109 is removed by the etching process, such that a dipole portion 221 covering the lightly doped region 117a is formed. In some embodiments, the portion of the dipole layer 121 over the top surface T3 (see FIG. 18) of the patterned mask 231 and the portion of the dipole layer 121 disposed over the lightly doped region 117b are removed by the etching process. The respective step is illustrated as the step S39 in the method 30 shown in FIG. 4.

In some embodiments, after the etching process is performed, the patterned mask 231 is separated from the dielectric layer 109 by the remaining portion of the dipole layer 121 (i.e., the dipole portion 221). In some embodiments, the dipole portion 221 is L-shaped from the cross-sectional view of FIG. 19. In some embodiments, the etching process includes a wet etching process, a dry etching process, or a combination thereof. After the dipole portion 221 is obtained, the patterned mask 231 may be removed. In some embodiments, the patterned mask 231 is removed by a stripping process, an ashing process, an etching process, or another suitable process.

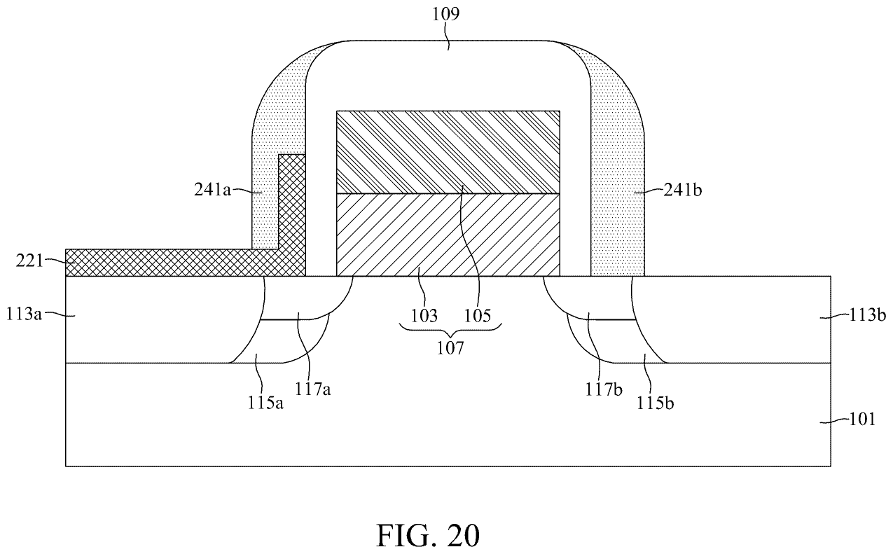

Subsequently, dielectric spacers 241a and 241b are formed on opposite sides of the gate structure 107, as shown in FIG. 20 in accordance with some embodiments. In some embodiments, the dielectric spacer 241a is formed over the dipole portion 221 and in direct contact with the dielectric layer 109, and the dielectric spacer 241b is formed over the lightly doped region 117b and in direct contact with the dielectric layer 109. In some embodiments, the dipole portion 221 is partially covered by the dielectric spacer 241a. The respective step is illustrated as the step S41 in the method 30 shown in FIG. 4. Some materials and processes used to form the dielectric spacers 241a and 241b of the semiconductor device 200 are similar to, or the same as those used to form the dielectric spacers 141a and 141b of the semiconductor device 100, and details thereof are not repeated herein.

Moreover, a source region 113a and a drain region 113b are formed in the semiconductor substrate 101, as shown in FIG. 20 in accordance with some embodiments. The respective step is illustrated as the step S43 in the method 30 shown in FIG. 4. In some embodiments, the source region 113a and the drain region 113b are located on opposite sides of the gate structure 107. In some embodiments, the source region 113a is formed penetrating through the lightly doped region 117a and the halo implant region 115a, and the drain region 113b is formed penetrating through the lightly doped region 117b and the halo implant region 115b. Some materials and processes used to form the source region 113a and the drain region 113b of the semiconductor device 200 are similar to, or the same as those used to form the source region 113a and the drain region 113b of the semiconductor device 100, and details thereof are not repeated herein.

Then, a dielectric layer 243 is formed covering the dipole portion 221, the dielectric spacers 241a, 241b, and the dielectric layer 109, an ILD layer 245 is formed covering the dielectric layer 243, and a source contact 251a and a drain contact 251b are formed in the ILD layer 245, as shown in FIG. 2 in accordance with some embodiments. In some embodiments, the source contact 251a penetrates through the ILD layer 245, the dielectric layer 243 and the dipole portion 221. In some embodiments, the drain contact 251b penetrates through the ILD layer 245 and the dielectric layer 243. Some materials and processes used to form the dielectric layer 243 and the ILD layer 245 of the semiconductor device 200 are similar to, or the same as those used to form the dielectric layer 143 and the ILD layer 145 of the semiconductor device 100, respectively, and details thereof are not repeated herein.

In some embodiments, the source contact 251a is electrically connected to the source region 113a, and the drain contact 251b is electrically connected to the drain region 113b. In some embodiments, the source contact 251a is in direct contact with the source region 113a, and the drain contact 251b is in direct contact with the drain region 113b. The respective steps are illustrated as the steps S43, S45 and S47 in the method 30 shown in FIG. 4.

Some materials and processes used to form the source contact 251a and the drain contact 251b of the semiconductor device 200 are similar to, or the same as those used to form the source contact 151a and the drain contact 151b of the semiconductor device 100, and details thereof are not repeated herein. After the source contact 251a and the drain contact 251b are formed, the semiconductor device 200 is obtained.

Embodiments of a semiconductor device with one dipole portion (e.g., the semiconductor device 200 with the dipole portion 221), a semiconductor device with two dipole portions (e.g., the semiconductor device 100 with the dipole portions 121a and 121b), and method for preparing the same are provided in the disclosure. The dipole portion(s) serve to increase the on-state current and/or suppress the off-state leakage current of the semiconductor device. In addition, parasitic capacitance in the portions of the channel between the gate structure (e.g., the gate structure 107) and the dipole portion(s) can be decreased to enhance the operation speed of the semiconductor device. As a result, the performance of the semiconductor device can be improved.

In one embodiment of the present disclosure, a semiconductor device is provided. The semiconductor device includes a gate structure disposed over a semiconductor substrate, and a dielectric layer surrounding the gate structure. The semiconductor device also includes a source region and a drain region disposed in the semiconductor substrate and on opposite sides of the gate structure. The semiconductor device further includes a first dipole portion disposed over the semiconductor substrate and covering the source region, and a first dielectric spacer disposed over the first dipole portion and adjacent to the dielectric layer.

In another embodiment of the present disclosure, a semiconductor device is provided. The semiconductor device includes a gate structure disposed over a semiconductor substrate, and a source region and a drain region disposed in the semiconductor substrate and on opposite sides of the gate structure. The semiconductor device also includes a first lightly doped region disposed in the semiconductor substrate and extending from the source region to the gate structure, and a first dipole portion disposed over the semiconductor substrate and covering the source region and the first lightly doped region. The semiconductor device further includes a first dielectric spacer covering the first dipole portion.

In yet another embodiment of the present disclosure, a method for forming a semiconductor device is provided. The method includes forming a gate structure over a semiconductor substrate, and forming a first dielectric layer covering the gate structure. The method also includes depositing a dipole layer over the semiconductor substrate and the first dielectric layer, and performing an etching process on the dipole layer to form a first dipole portion. The method further includes forming a first dielectric spacer over the first dipole portion, and forming a source region and a drain region in the semiconductor substrate and on opposite sides of the gate structure after the first dielectric spacer is formed. The source region is covered by the first dipole portion.

The embodiments of the present disclosure have some advantageous features. Depending on the conductivity type of the semiconductor device, the dipole portion covering the source region is configured to increase the on-state current and/or suppress the off-state leakage current of the semiconductor device. In addition, parasitic capacitance can be decreased to enhance the operation speed of the semiconductor device. As a result, the performance of the semiconductor device can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a gate structure disposed over a semiconductor substrate;
a dielectric layer surrounding the gate structure;
a source region and a drain region disposed in the semiconductor substrate and on opposite sides of the gate structure;
a first dipole portion disposed over the semiconductor substrate and covering the source region; and
a first dielectric spacer disposed over the first dipole portion and adjacent to the dielectric layer.

2. The semiconductor device of claim 1, wherein a top surface of the gate structure is covered by the dielectric layer.

3. The semiconductor device of claim 1, wherein the dielectric layer and the first dielectric spacer include different materials.

4. The semiconductor device of claim 1, wherein the first dielectric spacer is separated from the source region by the first dipole portion.

5. The semiconductor device of claim 1, further comprising:
a source contact penetrating through the first dipole portion to directly contact the source region.

6. The semiconductor device of claim 1, further comprising:
a first lightly doped region disposed in the semiconductor substrate and extending from the source region to the gate structure.

7. The semiconductor device of claim 6, wherein the first lightly doped region is in direct contact with the first dipole portion.

8. The semiconductor device of claim 6, wherein the first lightly doped region is separated from the first dielectric spacer by the first dipole portion.

9. The semiconductor device of claim 6, further comprising:
a first halo implant region disposed in the semiconductor substrate and extending from the source region to the gate structure, wherein the first lightly doped region is disposed over the first halo implant region.

10. The semiconductor device of claim 1, further comprising:
a second dipole portion disposed over the semiconductor substrate and covering the drain region, wherein a material of the first dipole portion is the same as a material of the second dipole portion.

11. The semiconductor device of claim 10, further comprising:
a drain contact penetrating through the second dipole portion to directly contact the drain region.

12. The semiconductor device of claim 10, further comprising:
a second dielectric spacer disposed over the second dipole portion and adjacent to the dielectric layer, wherein the second dielectric spacer is separated from the drain region by the second dipole portion.

13. The semiconductor device of claim 10, further comprising:
a second lightly doped region disposed in the semiconductor substrate and extending from the drain region to the gate structure, wherein the second lightly doped region is in direct contact with the second dipole portion.

14. The semiconductor device of claim 13, further comprising:
a second halo implant region disposed in the semiconductor substrate and extending from the drain region to the gate structure, wherein the second lightly doped region is disposed over the second halo implant region.
